(19) United States
(12) Patent Application Publication
(10) Pub. No.: US 2003/0015716 A1
(43) Pub. Date: Jan. 23, 2003

(54) Structure and method for fabricating an optical bus

(75) Inventor: George Valliath, Buffalo Grove, IL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/905,863

(22) Filed: Jul. 17, 2001

(51) Int. Cl. H01L 21/28; H01L 21/3205; H01L 33/00; H01L 27/15; H01L 31/12

(52) U.S. Cl. 257/81; 257/99

(57) ABSTRACT

An optical bus communicates data between external devices by sending and receiving emissions between an optical source and an optical detector within an enclosure. Each optical source may be paired with an optical detector to form a source-detector pair. The optical source and the optical detector can be formed within a semiconductor structure which forms at least part of the enclosure. The semiconductor structure includes high quality epitaxial layers of monocrystalline materials that can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. Any lattice mismatch between the accommodating buffer layer and the underlying silicon substrate is taken care of by the amorphous interface layer.

### FIELD OF THE INVENTION

This invention relates generally to semiconductor structures and devices and to a method for their fabrication, and more specifically to optical bus systems and devices utilizing semiconductor structures and devices that include a monocrystalline material layer comprised of semiconductor material, compound semiconductor material, and/or other types of material such as metals and non-metals.

### BACKGROUND OF THE INVENTION

Buses are generally implemented using electrical conductors to allow different components within a system to communicate. The rate of transferring information between the system components is determined by the bus width and the clock speed of the bus. Optimally, the clock speed of the bus is the same as the clock speed of the system components, such as a microprocessor. If the bus is too slow, it creates a bottleneck which can slow down the operation of the overall system. That is, the performance of the system, such as a computer, is not optimized because the bus system is not able to transfer the information fast enough. Future systems may include purely optical or electro-optical hybrids such that many communications within a system can be performed using optical sources and optical detectors. In such systems, a bus may still be required to interconnect various system components and allow them to communicate, but it needs to be able to operate as fast as the system components themselves. In effect, a bus within an optical or electro-optical system should be an optical bus.

Such buses would generally consist of optical sources and optical detectors, wherein the light generated by the optical sources would carry the information and the optical detectors would read the information. The bus would likely implement semiconductor devices for the optical sources and optical detectors, such as light emitting diodes (LEDs), semiconductor lasers, photodiodes, and the like. Such semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). While silicon is a generally good material for electrical components, it is a poor material from which to fabricate optical components because silicon emits light poorly and has a low absorption coefficient. However, silicon is a desirable substrate on which to grow monolithic layers to make compound semiconductors for optical devices. To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality. Thus, attempts to grow compound semiconductors necessary for optical sources on a foreign substrate such as silicon have also been unsuccessful.

If a large area thin film of high quality monocrystalline material was available at low cost, semiconductor optoelectronic devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material. Such semiconductor devices could be beneficially used for an optical bus. This could provide the bus with a clock speed in substantial agreement with a clock speed of the optical components of the system and prevent bottlenecking while keeping the overall cost of fabrication low.

Accordingly, a need exists for a high-speed optical bus utilizing optical devices fabricated from a semiconductor structure that provides a high quality monocrystalline film or layer over another monocrystalline material, and for a process for making such a structure. In other words, there is a need for providing the formation of a monocrystalline substrate that is compliant with a high quality monocrystalline material layer so that true two-dimensional growth can be achieved for the formation of quality semiconductor optical sources and optical detectors having grown monocrystalline film having with the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIG. 1 illustrates schematically, in cross section, a conceptual view of an optical bus in accordance with an embodiment of the invention;

FIGS. 2, 3, and 4 illustrate schematically, in cross section, semiconductor device structures in accordance with various embodiments of the invention;

FIG. 5 illustrates graphically the relationship between maximum attainable film thickness and lattice mismatch between a host crystal and a grown crystalline overlayer;

FIG. 6 illustrates a high resolution Transmission Electron Micrograph of a structure including a monocrystalline accommodating buffer layer;

FIG. 7 illustrates an x-ray diffraction spectrum of a structure including a monocrystalline accommodating buffer layer;

FIG. 8 illustrates a high resolution Transmission Electron Micrograph of a structure including an amorphous oxide layer;

FIG. 9 illustrates an x-ray diffraction spectrum of a structure including an amorphous oxide layer;

FIGS. 10-13 illustrate schematically, in cross-section, the formation of a device structure in accordance with another embodiment of the invention;

FIGS. 14-17 illustrate a probable molecular bonding structure of the device structures illustrated in FIGS. 10-13;

FIGS. 18-21 illustrate schematically, in cross-section, the formation of a device structure in accordance with still another embodiment of the invention;

FIGS. 22-24 illustrate schematically, in cross-section, the formation of yet another embodiment of a device structure in accordance with the invention;

FIG. 25 illustrates schematically, in cross section, a device structure that can be used in accordance with various embodiments of the invention; and

FIGS. 26-28 include illustrations of cross-sectional views of a portion of another integrated circuit that includes a semiconductor laser and a photodiode in accordance with what is shown herein.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

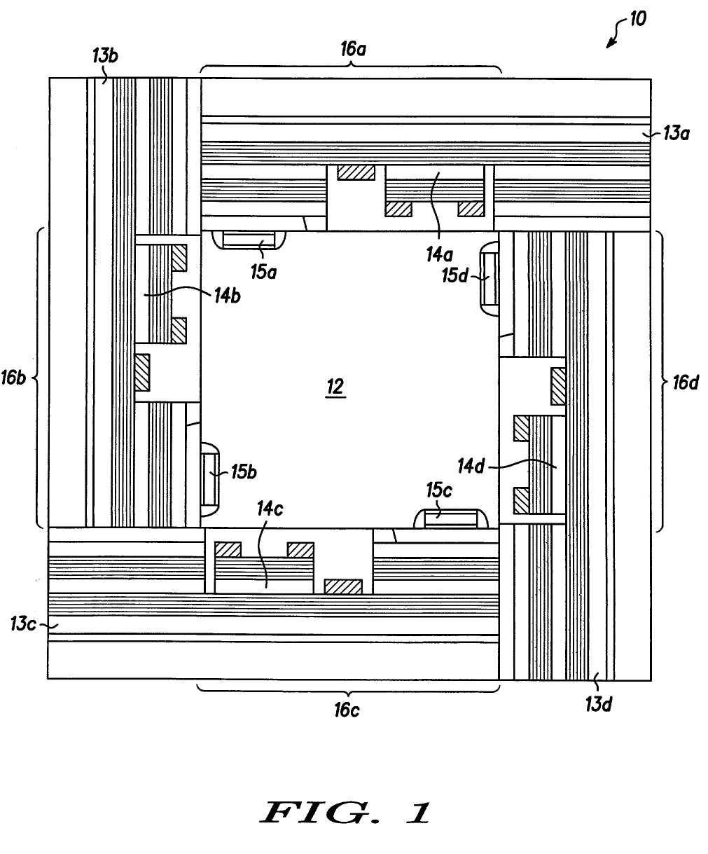

FIG. 1 illustrates, in cross-section, a portion of the bus 10 in accordance with an embodiment of the invention. The bus 10 generally includes a cavity or enclosure 12 defined by several sides 13a-13d. In accordance with one aspect of this embodiment, the enclosure 12 is in the shape of a cube having a top (not shown), a bottom (not shown), and four sides 13a-13d. On the inner face of each side 13a-13d of the bus 10 there is preferably an optical source 14a-14d associated with an optical detector 15a-15d together forming a source-detector pair 16a-16d. In order to provide communication from one system component to another system component, the bus 10 preferably has at least one optical source 14a to emit light and one optical detector 15c to detect the light. However, as it will be shown below, the bus 10 is not limited to a particular shape, and is not limited to having a source-detector pair 16 on each side 13. The sides 13a-13d are formed from a semiconductor structure as described below, with a semiconductor substrate common to both the optical source 14a-14d and the optical detector 15a-15d of each source-detector pair 16a-16d.

The transmitted information is communicated from one system component to another system component via the optical bus 10 with each system component coupled to one or more of the optical sources 14a-14d and/or optical detectors 15a-15d. For example, a computer has many system components including processing circuitry, such as a microprocessor, and external circuitry, such as a data storage unit, and various other external circuitry which need to exchange information. The system components and external circuitry may be assigned an address and each address may be assigned a source-detector pair 16. Other methods of associating transmissions with particular system components and external circuitry are also possible, including associating a particular wavelength of light to an address, system component or external circuitry, or utilizing one source-detector pair 16 for communication of each data bit. For example, in a sixteen bit communication (i.e. a sixteen bit bus width), there may be sixteen source-detector pairs. Thus, the number of source-detector pairs may determine the width of the bus 10. The transmission may also have a header that designates the transmitting system component or external circuitry and the intended receiving system component or external circuitry which can be read by each optical detector 15a-15d to determine whether it is the intended recipient or not. In accordance with the present invention, the transmission is made via light signals which may be in the form of pulses or variations in duration, power, wavelength and/or frequency, or any other method of encoding. The transmission may also be analog or digital in nature.

In operation, the optical source 14 of a source-detector pair 16 may be configured to generate light (e.g., photons) based on receiving electrical signals from an electrical signal connection with the system component or external circuitry. An optical detector 15 in another source-detector pair 16 may be optically connected to the optical source 14 to generate electrical signals based on detecting light generated by the optical source 14. Information that is communicated between the optical source 14 and optical detector 15 components may be digital or analog.

If desired, the reverse of this configuration may be used. An optical source 14 that is responsive to the on-board processing circuitry may be coupled to an optical detector 15 to have the optical source 14 generate an electrical signal for use in communications with the system component or external circuitry. A plurality of such optical component pair structures may be used for providing two-way connections. In some applications where synchronization is desired, a first pair of optical components may be coupled to provide data communications and a second pair may be coupled for communicating synchronization information.

In one embodiment, a transmission from some system components or external circuitry is communicated to the optical source 14 associated with the transmitting system component or external circuitry. In response to the transmission, the optical source 14 emits the light signal into the enclosure 12 to be detected by the optical detector 15 associated with the receiving system component or external circuitry. The light emitted from the optical source 14a is preferably not coupled or otherwise guided, so that the enclosure 12 is filled with the light and can be detected by all other optical detectors 15b-15d. This allows concurrent communication with various system components and/or external circuitry if necessary, and further allows any of the optical detectors 15b-15d to be able to receive a transmission emitted from the optical source 14a. Thus, in accordance with one embodiment of the invention, the optical source 14 is an omnidirectional optical source. The only optical detector that will generally not detect the light is the one that is paired with the emitting optical source 14a (i.e. optical detector 15a). Since the emitting optical source 14a is associated with the same address as the non-detecting optical detector 15a, there is no reason for that address to read itself. The other optical detectors 15b-15d can “listen” for their address by reading the header information being transmitted to the enclosure 12, detecting only certain wavelengths associated with its address or any other method conducive to the manner of designating the intended receiving system component or external circuitry.

In accordance with an embodiment of the invention, the inner faces of the sides preferably minimize reflections. In some cases, having reflections within the enclosure 12 could cause problems. When optical source 14a emits light, the other optical detectors 15b-15d only need to see each bit of information once. If the inner surfaces of the sides were reflective, the light would reflect off of the surfaces multiple times and could be read by the intended optical detector 15 multiple times. Furthermore, the more reflections there are the longer it takes to complete the transmission. Other source-detector pairs 16b-16d may not be able to communicate until the reflections have ceased, thus causing a delay and possibly slowing down the system. While the multiple reflections could be compensated for, and perhaps even used as an error detection technique similar to redundant transmissions, it is preferred that the reflections be kept to a minimum.

Generally, the reflectivity of the semiconductor structure around an optical source and an optical detector is already low. For example, silicon transmits most infrared wavelengths and has a higher absorption coefficient for wavelengths near the ultraviolet spectrum. Compound semiconductor structures generally absorb most wavelengths of light. However, for those materials that transmit certain wavelengths, such as infrared light through silicon, it is desirable to include an additional material or coating with a high absorption coefficient for the particular wavelength being used. Therefore, in one embodiment the underside of the semiconductor substrate may be coated with flat black paint which adequately absorbs most wavelengths of light. However, any material or coating with a high absorption coefficient may be used and may further be applied to one or more of the inner faces around the optical source 14 and optical detector 15 to cover any reflective areas, such as metallic layers or components. This may be done using materials and methods as are well known in the art. The particular choice of material or coating may be dependent on the particular wavelength(s) being used since some materials have a high absorption coefficient with respect to some wavelengths but not other wavelengths.

In accordance with a different embodiment of the invention, reflections within the enclosure 12 may become necessary if there is an array of source-detector pairs 16 on an inner face. In order for an optical detector from one source-detector pair to be able to read an optical source from another source-detector pair that is on the same face, the light emitted from the optical source needs to reflect off of another surface of the enclosure 12 in order to reach the optical detector 15. However, as noted above, once the optical detector 15 reads the information it does not need to read it again. Therefore, it may be desirable to control the number of reflections by utilizing a material or coating on the surface of the semiconductor structure that allows for enough reflection for the optical detector 15 to be able to detect and read the reflected light. This can be accomplished by suitably setting the detection threshold for the optical detectors 15. The surface would allow for some absorption of the light on the first reflection. On subsequent reflections the light is absorbed such that it can no longer be read by the optical detector 15. The optical detector 15 then only detects the light once and reads the information only once. In an alternative embodiment, small reflectors, such as metallic surfaces or mirrors, may be formed on the surface. The reflectors may be positioned as to reflect emissions from an optical source 14 to an intended optical detector 15. The size of the reflector would be such that preferably all of the reflected light is focused on and absorbed by the optical detector upon the initial reflection.

A further consideration in using reflective surfaces is the effect it has on the speed of the bus 10. With the optical source 14a on one face and the optical detector 15c on the opposing face, the farthest the light has to travel is the width of the enclosure 12. When the optical source and optical detector are on the same face, the light must reflect off another surface and come back, thus traveling as much as twice the distance of the enclosure 12. This could increase latency of the signals being transmitted through bus 10, depending on the roundtrip time of the signals within the enclosure 12. If this becomes an issue, a possible solution may be to use smaller dimensions for the enclosure 12. Preferably, the enclosure 12 would be dimensioned for a specified maximum latency. For example, for a 5 GHz clock cycle and a maximum latency of 1 clock cycle, the roundtrip distance within the enclosure 12 should be no more than 6 cm. However, if more latency can be tolerated, a greater roundtrip distance may be used.

In an alternative embodiment, source detector pairs 16 on the same inner face may be electronically coupled to one another so as to communicate electronically with other source-detector pairs 16 on the same face and communicate optically with source detector pairs on a different face. However, for those embodiments where there are many source detector pairs on the same face, it may be preferable to only use optical interconnections as opposed to electrical interconnections. For dense interconnections, electrical communications between all the devices require many electrical lines and conductors. This in turn may lead to transmission line delays and signal skews between communications with one system component and another system component that are intended to be simultaneous. Therefore, optical connections may be preferred for simultaneous or near simultaneous communication with little or no skew between communication with one system component and communication with another system component. That is, information transmitted from one optical source and intended for multiple detectors is received by each detector almost simultaneously with little or no skew between receiving the communication at one detector and receiving the communication at the other detector.

For those embodiments where an array of source-detector pairs has been formed with multiple source-detector pairs on a common face, some skew may occur between communicating with an adjacent detector and communicating with a detector farther away on the array. For example, if the communication is being achieved by reflecting the emissions from the source off of a reflective surface, the distance for the emission to travel to an adjacent detector is shorter than the required travel distance to a detector that is positioned farther away on the array. Therefore, it may be desirable to curve or otherwise shape the reflective surfaces so as to shorten the distance the light has to travel to reach the various detectors, thereby reducing the skew in transmitting to multiple detectors on the same face. The particular shape that is utilized may be dependent on such design factors as the array layout, the surface area of the array, the roundtrip distance within the enclosure 12, the maximum tolerable skew, the maximum tolerable latency, as well as any other factors that may affect the skew. These and other factors may be taken to account, as is known in the art, to shape the reflective surface so as to minimize latency and minimize skew. Alternatively, various coatings, wave guides or defraction gratings may be implemented, as is known in the art, to reduce the path distance of the light.

As mentioned above, neither the shape nor the number of sides of the enclosure 12 are limited, though the enclosure 12 is preferably a closed area. The number of inner faces, the shape of the enclosure 12, and the number of source-detector pairs 16 can vary according to the requirements of the system in which the bus 10 is implemented. For example, if the system has ten components that need to communicate within the system, the bus 10 could have ten source-detector pairs. If the bus 10 is set up to have one source-detector pair 16 per inner face, the enclosure 12 will have at least ten sides. It should be noted that while it is preferred that each side 13 have a single source-detector pair 16, it is not required. Some faces may have more source-detector pairs than others, and some faces may have none.

In accordance with the present invention, each source-detector pair 16 and the corresponding structures for the optical source 14 and the optical detector 15 are formed on the same semiconductor substrate, preferably silicon. However, as discussed above, if the optical source 14 were to be formed from gallium arsenide (GaAs), which has a lattice constant of about 5.653 Å, directly on a silicon substrate, which has a lattice constant of about 5.431 Å, dislocations and defects would form in the semiconductor structure. This effect may occur with any compound semiconductor formed directly on a foreign substrate where the difference in the lattice constant between the two is greater than 4%. Even a difference of less than 4% can cause some strain on the semiconductor structure. The solution to this problem is found by introducing one or more layers between the substrate and the semiconductor structure which compensate for the structural difference between the substrate and the semiconductor structure. The semiconductor structure upon which the source-detector pair 16 is formed is described in greater detail below and is applicable to any device which may be used for the optical source 14 and/or optical detector 15.

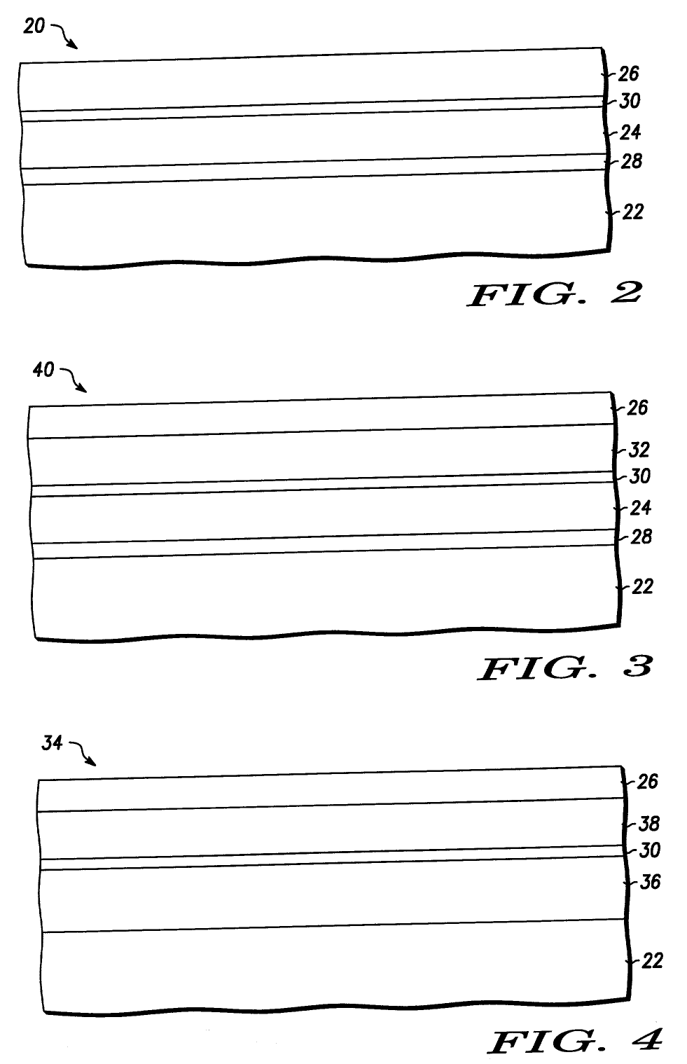

FIG. 2 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide.

Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 3 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 4 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 2 and 3 are adequate for growing monocrystalline material layers over a monocrystalline substrate. However, the process described in connection with FIG. 4, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of S_{rz}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45-degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 nm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygenarsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45-degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 3. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 3. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 4. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 2-4, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

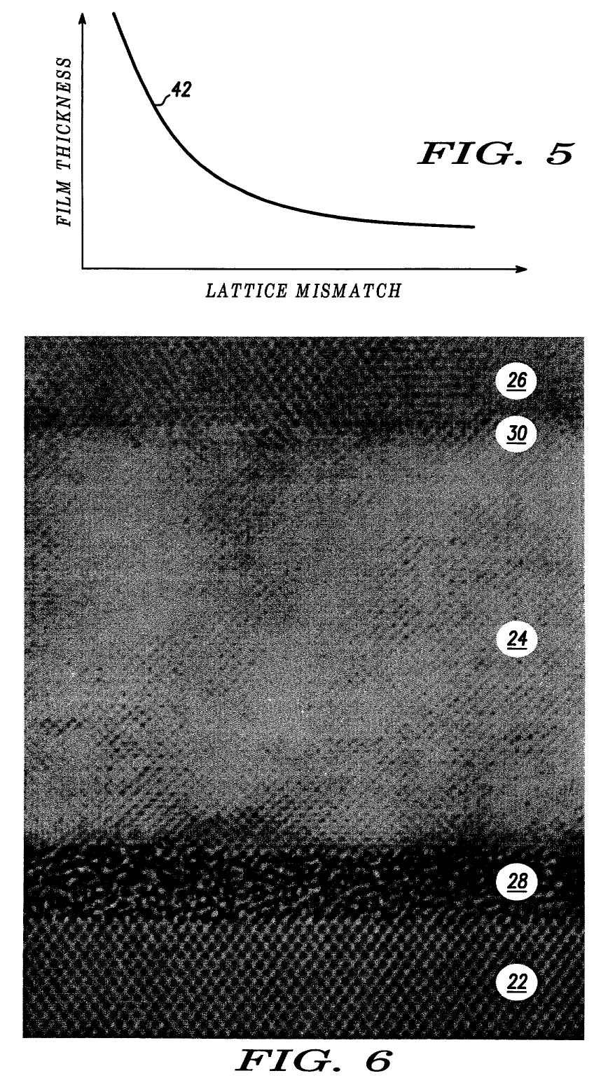

FIG. 5 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 2-4, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 2-4. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 6 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

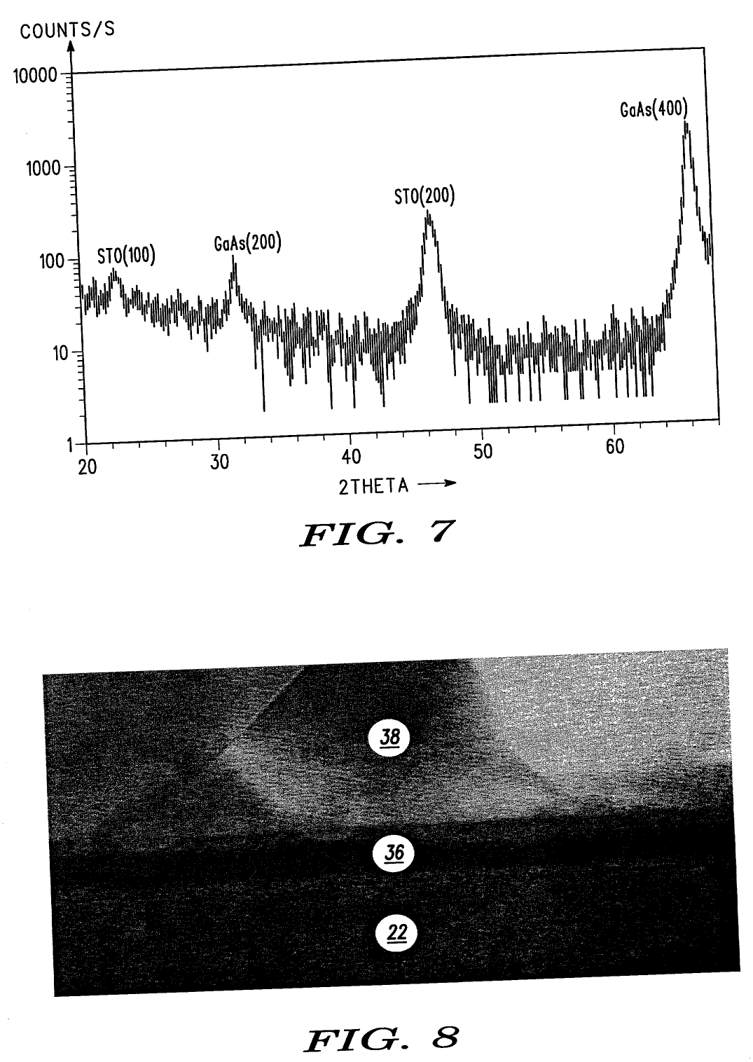

FIG. 7 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 3 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 4, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 8 is a high resolution TEM of semiconductor material manufactured in accordance with the embodiment of the invention illustrated in FIG. 4. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

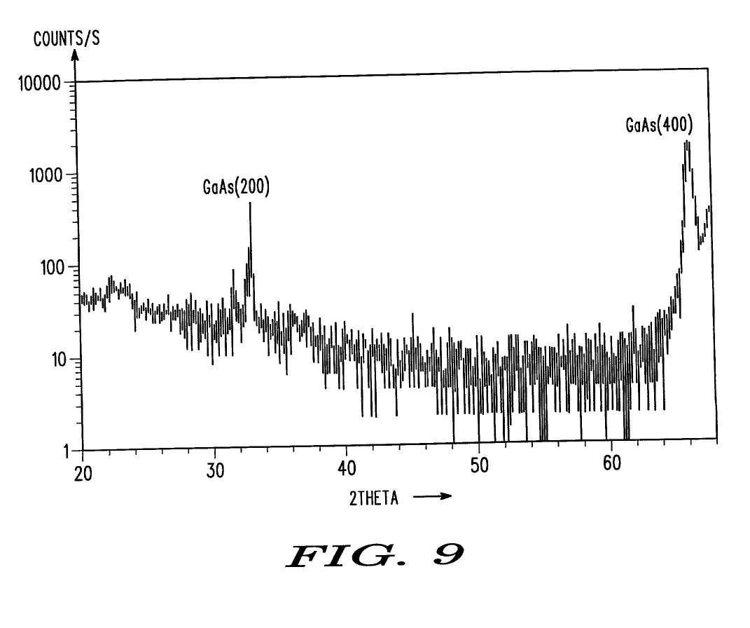

FIG. 9 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

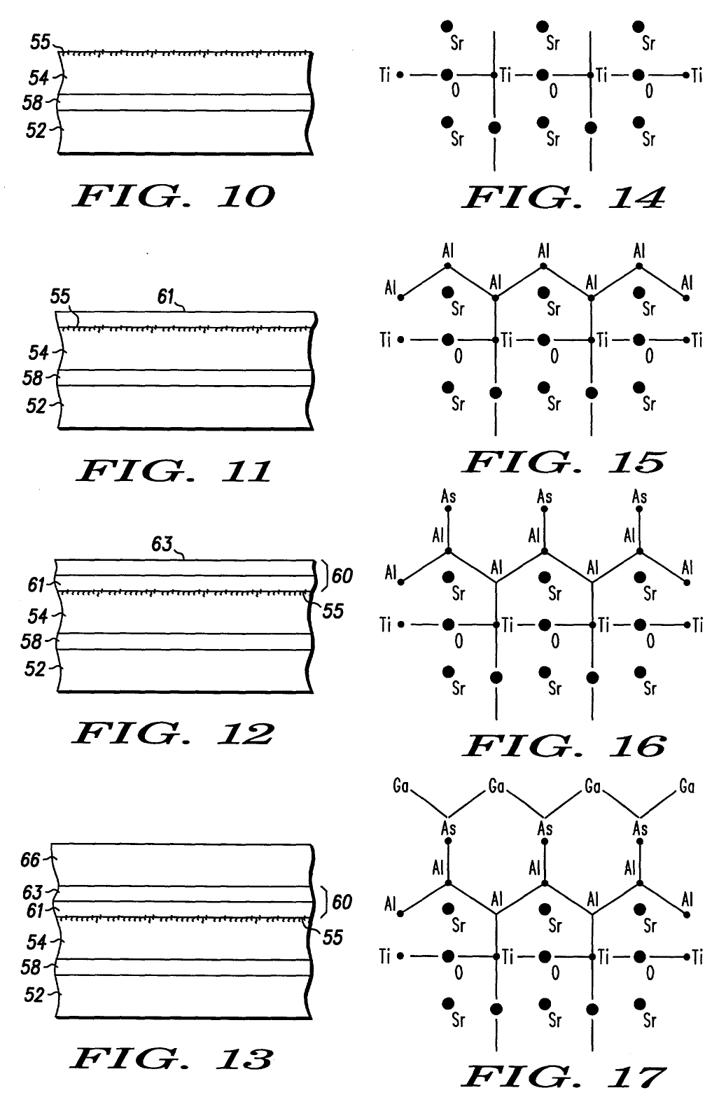

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide. The formation of a device structure in accordance with another embodiment of the invention is illustrated schematically in cross-section in FIGS. 10-13. Like the previously described embodiments referred to in FIGS. 2-4, this embodiment of the invention involves the process of forming a compliant substrate utilizing the epitaxial growth of single crystal oxides, such as the formation of accommodating buffer layer 24 previously described with reference to FIGS. 2 and 3 and amorphous layer 36 previously described with reference to FIG. 4, and the formation of a template layer 30. However, the embodiment illustrated in FIGS. 10-13 utilizes a template that includes a surfactant to facilitate layer-by-layer monocrystalline material growth.

Turning now to FIG. 10, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 2 and 3 and any of those compounds previously described with reference to layer 36 in FIG. 4 which is formed from layers 24 and 28 referenced in FIGS. 2 and 3.

Layer 54 is grown with a strontium (Sr) terminated surface represented in FIG. 10 by hatched line 55 which is followed by the addition of a template layer 60 which includes a surfactant layer 61 and capping layer 63 as illustrated in FIGS. 11 and 12. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 11 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 12. Surfactant layer 61 may be exposed to a number of materials to create capping layer 63 such as elements which include, but are not limited to, As, P, Sb and N. Surfactant layer 61 and capping layer 63 combine to form template layer 60. Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 13.

FIGS. 14-17 illustrate possible molecular bond structures for a specific example of a compound semiconductor structure formed in accordance with the embodiment of the invention illustrated in FIGS. 10-13. More specifically, FIGS. 14-17 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 2 and 3, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 11-13 to increase the surface energy of the monocrystalline oxide layer 54 and also to shift the crystalline structure of the template to a diamond-like structure that is in compliance with the original GaAs layer.

FIG. 14 illustrates the molecular bond structure of a strontium terminated surface of a strontium titanate monocrystalline oxide layer. An aluminum surfactant layer is deposited on top of the strontium terminated surface and bonds with that surface as illustrated in FIG. 15, which reacts to form a capping layer comprising a monolayer of Al₂Sr having the molecular bond structure illustrated in FIG. 15 which forms a diamond-like structure with an sp³ hybrid terminated surface that is compliant with compound semiconductors such as GaAs. The structure is then exposed to As to form a layer of AlAs as shown in FIG. 16. GaAs is then deposited to complete the molecular bond structure illustrated in FIG. 17 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 18-21, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 18. Monocrystalline oxide layer 74 may be comprised of any of those materials previously discussed with reference to layer 24 in FIGS. 2 and 3, while amorphous interface layer 78 is preferably comprised of any of those materials previously described with reference to the layer 28 illustrated in FIGS. 2 and 3. Substrate 72, although preferably silicon, may also comprise any of those materials previously described with reference to substrate 22 in FIGS. 24.

Next, a silicon layer 81 is deposited over monocrystalline oxide layer 74 via MBE, CVD, MOCVD, MEE, ALE, PVD, CSD, PLD, and the like as illustrated in FIG. 19 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 20. The formation of amorphous layer 86 is similar to the formation of layer 36 illustrated in FIG. 4 and may comprise any of those materials described with reference to layer 36 in FIG. 4 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from Groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing Group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

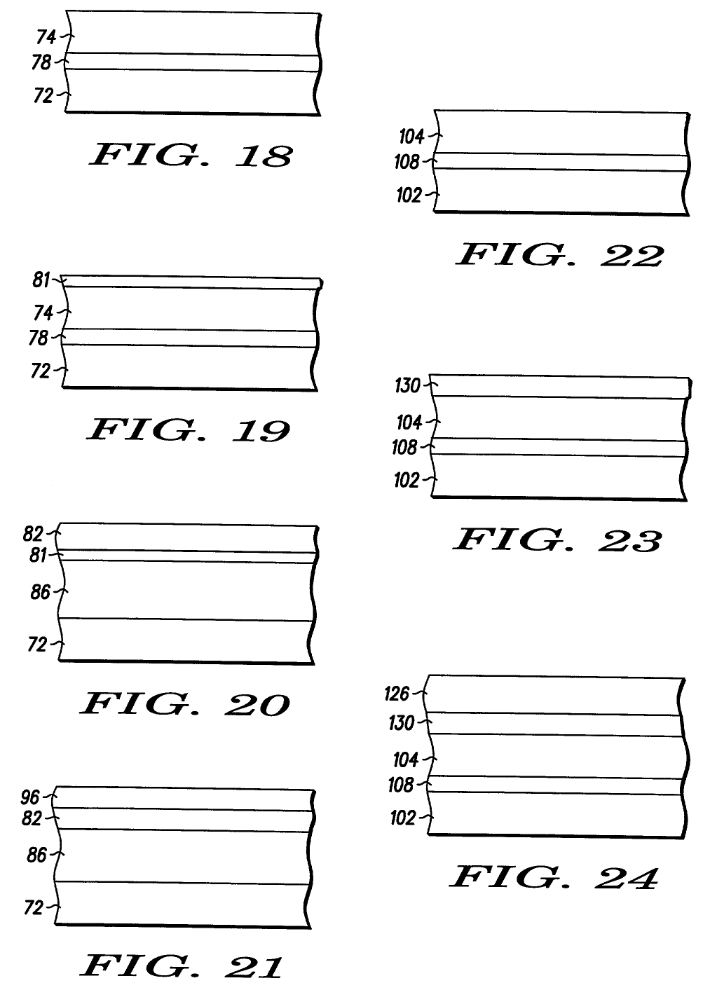

FIGS. 22-24 schematically illustrate, in cross-section, the formation of another embodiment of a device structure in accordance with the invention. This embodiment includes a compliant layer that functions as a transition layer that uses clathrate or Zint1 type bonding. More specifically, this embodiment utilizes an intermetallic template layer to reduce the surface energy of the interface between material layers thereby allowing for two dimensional layer by layer growth.

The structure illustrated in FIG. 22 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 2 and 3. Amorphous interface layer 108 may comprise any of those materials previously described with reference to amorphous interface layer 28 in FIGS. 2 and 3. Substrate 102 is preferably silicon but may also comprise any of those materials previously described with reference to substrate 22 in FIGS. 2-4.

A template layer 130 is deposited over accommodating buffer layer 104 as illustrated in FIG. 23 and preferably comprises a thin layer of Zint1 type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu, Yb)In₂, BaGe2As, and SrSn₂As₂

A monocrystalline material layer 126 is epitaxially grown over template layer 130 to achieve the final structure illustrated in FIG. 24. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zint1 phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zint1 type template layer used in this embodiment can absorb a large strain without a significant energy cost. In the above example, the bond strength of the Al is adjusted by changing the volume of the SrAl₂ layer thereby making the device tunable for specific applications which include the monolithic integration of Group III-V and Si devices and the monolithic integration of high-k dielectric materials for CMOS technology.

Attention is now directed to forming exemplary portions of illustrative composite semiconductor structures or composite integrated circuits like a source-detector pair. A composite integrated circuit may include a pair of optical components, such as an optical source component and an optical detector component. An optical source component may be a light generating semiconductor device, such as an optical laser, a photo emitter, a diode, etc. An optical detector component may be a light-sensitive semiconductor junction device, such as a photodetector, a photodiode, a bipolar junction device, a transistor, CMOS image sensor, a charged coupled device (CCD) sensor, etc.

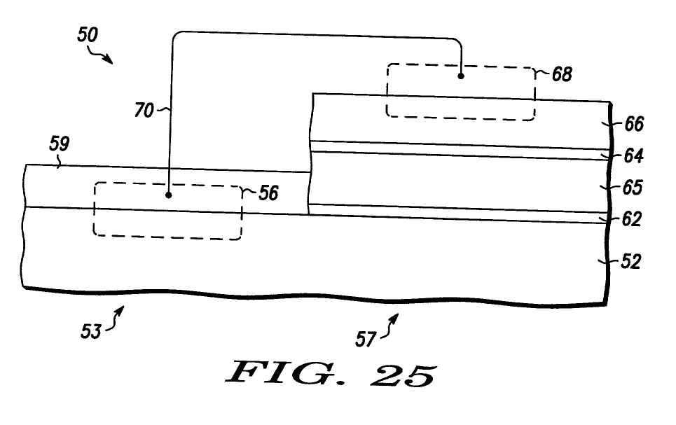

FIG. 25 illustrates schematically, in cross section, a source-detector pair 50 in accordance with an embodiment of the invention. Source-detector pair 50 includes a monocrystalline semiconductor substrate 52, preferably a monocrystalline silicon wafer. Monocrystalline semiconductor substrate 52 includes two regions, 53 and 57. An optical detector of a source-detector pair generally indicated by the dashed line 56 is formed, at least partially, in region 53. Optical detector 56 can be a photodiode, a p-i-n photodiode, an avalanche photodiode, or any other suitable silicon integrated photo detection device. The p-i-n photodiode is suitable for most applications, though the avalanche photodiode may be used for higher speeds. In accordance with an alternate embodiment of the invention, the optical detector may be formed from a compound semiconductor structure, such that both the optical source and the optical detector are compound semiconductor devices, or the optical detector is a compound semiconductor device and the optical source is a Group IV device, or any other possible combination. The optical detector in region 53 can be formed by conventional semiconductor photodetector processing as well known and widely practiced in the semiconductor industry. A layer of insulating material 59 such as a layer of silicon dioxide or the like may overlie the surrounding substrate surface of region 53.

Insulating material 59 and any other layers that may have been formed or deposited during the processing of optical detector 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 62 and 65 may be subject to an annealing process as described above in connection with FIG. 4 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, an optical source of the source-detector pair, generally indicated by a dashed line 68 is formed in compound semiconductor layer 66. Optical source 68 can be formed by processing steps conventionally used in the fabrication of gallium arsenide or other Group III-V compound semiconductor optical devices. Optical source 68 can be any active or passive component such as a semiconductor laser, photo emitter, or any other optical source component that utilizes and takes advantage of physical properties of compound semiconductor materials. The formation of a compound semiconductor laser is described more fully below. Preferably, the optical source component is an uncoupled light emitting diode (LED). An uncoupled LED, without a waveguide or other device for directing and/or collimating the light, has a generally large beam divergence angle. With enough power, light from an LED can ordinarily reach an optical detector on an opposing side in a small enclosure (12 as shown in FIG. 1). The dispersion of light in the enclosure is preferably uniform so each optical detector detects substantially the same amount of radiation.

A metallic conductor schematically indicated by the line 70 can be formed to electrically couple optical source 68 and optical detector 56, thus implementing an integrated source-detector pair that includes at least one optical detector formed in silicon substrate 52 and one optical source formed in monocrystalline compound semiconductor material layer 66. Although illustrative source-detector pair 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

In still another embodiment, an integrated circuit can be formed such that it includes an optical laser in a compound semiconductor portion and an optical detector within a Group IV semiconductor region of the same integrated circuit. A compound semiconductor laser, such as a vertical cavity surface emitting laser (VCSEL), may be preferred over an LED in certain applications, for example, if the nature of the detector or the optical bus 10 requires a greater amount of power from the optical source. FIGS. 26-28 include illustrations of one embodiment. While a laser would be able to emit light of sufficient power, the divergence of light from a semiconductor laser is generally less than that of an LED. In such an embodiment, it may be necessary to include a material on the emitting potion of the laser that would disperse the light for the laser. This could be any suitable material or device capable of dispersing, diffusing, scattering or otherwise filling the enclosure 12 with the laser light.

For example, a diffusely reflective surface coating on opposing sides would help to disperse the beam. In one embodiment, a polymeric encapsulate embedded with transparent glass beads may be used to create a white scattering material that would disperse the laser light throughout the enclosure 12. A lens or dome-shaped encapsulate of a transparent dielectric material having a high refractive index over the laser may also be sufficient.

FIG. 26 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 4 to form a single amorphous accommodating layer. In this specific embodiment, the layers needed to form the optical laser will be formed first, followed by the layers needed for the optical detector. In FIG. 26, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 4 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

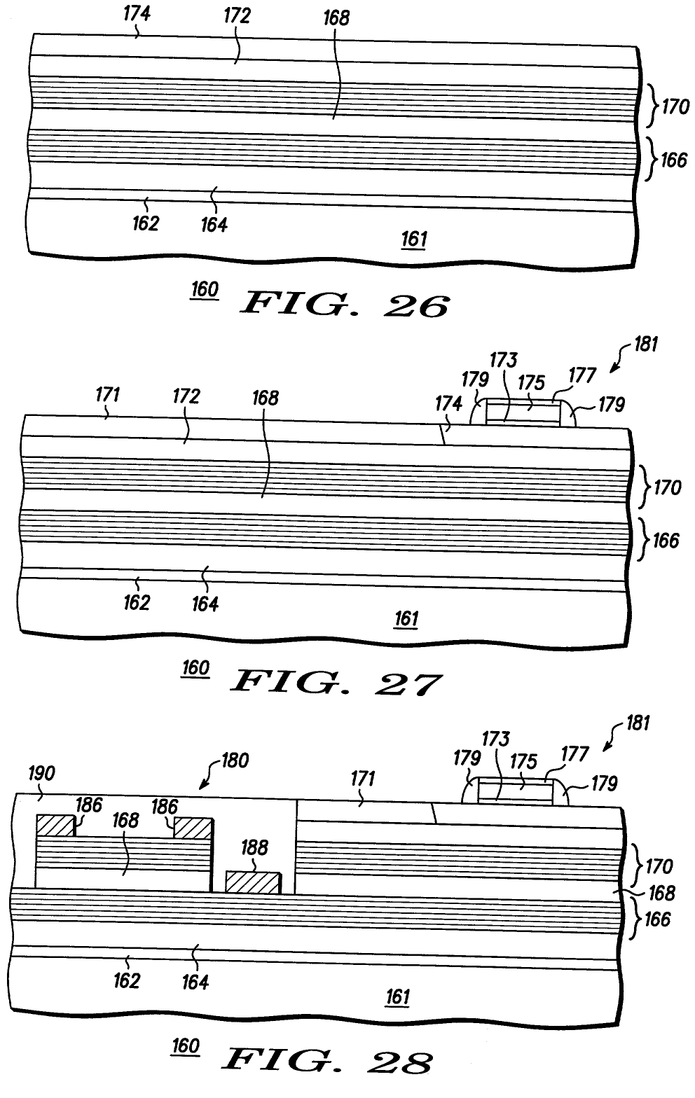

In FIG. 27, the optical detector portion is processed to form a p-i-n photodiode 181 upon this upper monocrystalline Group IV semiconductor layer 174, which can be P-doped. As illustrated in FIG. 27, a field isolation region 171 is formed from a portion of layer 174. A P⁺ doped layer 173 is formed over the layer 174, and an intrinsic layer 175 is formed over the P⁺ doped layer 173. N⁺ doped region 177 is formed over the intrinsic layer 175 to complete the p-i-n structure, as shown. Sidewall spacers 179 are formed adjacent to the vertical sides of the intrinsic layer 175.

The next set of steps is performed to define the optical laser 180 as illustrated in FIG. 28. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 28. Contact 186 has an annular shape to allow light (photons) to pass out of the upper mirror layer 170 into the enclosure 12. A polymeric encapsulate 190 embedded with transparent glass beads, as described above, may then be formed over the optical laser 180 using glob-top techniques, as known in the art of semiconductor device manufacture. The beads may be on the order of ten microns in diameter for effective dispersion of the laser emission.

A number of these semiconductor structures can be joined to create various polyhedral structures as represented in FIG. 1, and the number of optical sources and optical detectors on each semiconductor structure can vary from none to an array of source-detector pairs. Furthermore, not all sides need to be made of the semiconductor structure described herein, though those sides with an optical source and/or optical detection are preferably made from this semiconductor structure. In one embodiment, the integrated circuit is positioned on its side with the optical source and the optical detector facing inward towards the enclosure 12. This can be done with several integrated circuits formed similar to the one above. The edges of each semiconductor structure may then be joined to close up and form the enclosure 12. Preferably, the enclosure 12 is closed off to any external light that may interfere with the optical detectors or otherwise affect the optical bus. In an alternative embodiment, the integrated circuit is positioned over another integrated circuit with opposing faces and with the semiconductor structure remaining horizontal. Spacers may be implemented to separate the integrated circuits and form the enclosure 12. Side-emitting sources and side-detectors are also possible and could all be formed from the same semiconductor substrate similar to the techniques described above. Once all the side-emitting sources and detectors are formed, the semiconductor structure may be etched out or otherwise to define the sides of the enclosure 12 and expose each device.

The composite integrated circuit may further include processing circuitry that is formed at least partly in the Group IV semiconductor portion of the composite integrated circuit. The processing circuitry, or other system component, is configured to communicate with the external circuitry to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry or other system components. Optical components in the composite integrated circuit may provide the optical communications connections which may electrically isolate the electrical signals in the communications connections from the processing circuitry. Together, the electrical and optical communications connections may be for communicating information, such as data, control, timing, etc. Information that is received or transmitted between the source-detector pairs may be from or for the electrical communications connection between the external circuitry, or between the external circuitry and the system components. The optical components and the electrical communications connection may form a communications connection between the processing circuitry and the external circuitry while providing electrical isolation for the processing circuitry. If desired, a plurality of source-detector pairs may be included in the composite integrated circuit for providing a plurality of communications connections and for providing isolation, thus providing an array of source-detector pairs within a common monocrystalline silicon substrate.

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

By the use of this type of substrate, the wafer is essentially a relatively inexpensive “handle” wafer used during the fabrication of the compound semiconductor components within a monocrystalline compound semiconductor layer overlying the wafer. This “handle” wafer overcomes the fragile nature of the compound semiconductor wafers by placing them over a relatively more durable and easy to fabricate base material. Therefore, an integrated circuit can be formed such that all optical components, and particularly all active optical devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers. Therefore, optical components can be formed within III-V or II-VI semiconductor materials over a wafer of at least approximately 200 millimeters in diameter and possibly at least approximately 300 millimeters.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may integrate both the optical source and the optical detector so as to include light emitting diodes, lasers, photodetectors, diodes, or the like. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase. Furthermore, the present invention provides an optical bus system that utilizes the advantages of a monocrystalline substrate that is compliant with a high quality monocrystalline material layer in order to implement the necessary optical components.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. An optical bus comprising:
an enclosure having at least a first side and a second side each comprising a semiconductor structure, wherein the semiconductor structure comprises:
a monocrystalline silicon substrate;
an amorphous oxide material overlying the monocrystalline substrate;
a monocrystalline perovskite oxide material overlying the amorphous oxide material; and
a monocrystalline compound semiconductor material overlying the monocrystalline perovskite oxide material;
a first source-detector pair formed within the semiconductor structure of the first side, wherein the first source-detector pair comprises a first semiconductor optical source and a first semiconductor optical detector; and
a second source-detector pair formed within the semiconductor structure of the second side, wherein the second source-detector pair comprises a second semiconductor optical source and a second semiconductor optical detector.

2. The optical bus of claim 1, wherein the second semiconductor optical detector is capable of detecting emissions from the first semiconductor optical source.

3. The optical bus of claim 1, wherein one or more inner surfaces of the enclosure are substantially nonreflective to emissions from the first and second semiconductor optical sources.

4. The optical bus of claim 1, wherein the first side has multiple source-detector pairs each having a semiconductor optical source and a semiconductor optical detector formed within the semiconductor structure, and the second side has an inner surface wherein at least a portion of the inner surface is at least partially reflective to emissions from the semiconductor optical sources.

5. The optical bus of claim 4, wherein two or more of the multiple source-detector pairs are electrically interconnected.

6. The optical bus of claim 4, wherein the at least partially reflective portion of the inner surface is shaped to compensate for signal latency.

7. The optical bus of claim 1, wherein at least one semiconductor optical detector is one of a Group IV semiconductor optical device and a compound semiconductor optical device.

8. The optical bus of claim 1, wherein at least one semiconductor optical source is one of a Group IV semiconductor optical device and a compound semiconductor optical device.

9. The optical bus of claim 1 further comprising a emission-dispersing material over at least one of the semiconductor optical sources.

10. The optical bus of claim 9, wherein the emission-dispersing material is one of a transparent, dielectric encapsulate having a high index of refraction, and a transparent, polymeric encapsulate embedded with particles, wherein the particles have an index of refraction different from the polymeric material.

11. The optical bus of claim 1, wherein the first source-pair is coupled to a first device external to the optical bus and the second source-detector pair is coupled to a second device external to the optical bus, wherein the first device transmits information to the second device via the second semiconductor optical detector detecting emissions from the first semiconductor optical source.

12. The optical bus of claim 1 further comprising processing circuitry formed at least partially within the semiconductor structure.

13. An optical bus comprising:
a first side having a first surface, the first side comprising a semiconductor structure, wherein the semiconductor structure comprises:
a monocrystalline silicon substrate;
an amorphous oxide material overlying the monocrystalline substrate;
a monocrystalline perovskite oxide material overlying the amorphous oxide material; and
a monocrystalline compound semiconductor material overlying the monocrystalline perovskite oxide material;
a first and second source-detector pair formed within the semiconductor structure, wherein each source-detector pair comprises a semiconductor optical source and a semiconductor optical detector; and
a second side having a second surface, wherein at least a portion of the second surface is at least partially reflective to emissions from one or more of the semiconductor optical sources;
wherein one or more of the semiconductor optical detectors are capable of detecting the reflected emissions, and wherein the first and second surfaces are closed off to external radiative emissions.

14. The optical bus of claim 13, wherein one or more of the first surface and the second surface comprise an emission-dispersing material.

15. The optical bus of claim 13, wherein the at least partially reflective portion of the second surface is shaped to compensate for signal latency.

16. The optical bus of claim 13, wherein one or more of the first surface and the second surface are partially absorptive to the emissions.

17. The optical bus of claim 13, wherein the second side comprises the semiconductor structure, the optical bus further comprising one or more source-detector pairs formed within the semiconductor structure of the second side.

18. The optical bus of claim 17, wherein at least a portion of the first surface is at least partially reflective to emissions from the one or more of the semiconductor optical sources of the second side.

19. The optical bus of claim 18, wherein the at least partially reflective portion of the first surface is shaped to compensate for signal latency.

20. A process for fabricating an optical bus comprising:
forming one or more source-detector pairs from a semiconductor structure, the step of forming comprising the steps of:
providing a monocrystalline silicon substrate;
depositing a monocrystalline perovskite oxide film overlying the second region of the monocrystalline silicon substrate, the film having a thickness less than a thickness of the material that would result in strain-induced defects;
forming an amorphous oxide interface layer at an interface between the monocrystalline perovskite oxide film and the monocrystalline silicon substrate;
epitaxially forming a monocrystalline compound semiconductor layer overlying the monocrystalline perovskite oxide film; and
forming one or more optical devices within the monocrystalline compound semiconductor layer, wherein each optical device is one of an optical detector and an optical source;
forming an enclosure using the semiconductor structure, wherein the one or more optical devices face an inside of the enclosure; and
sealing the enclosure off from external radiative emissions.

21. The method of claim 20, wherein the step of forming one or more source-detector pairs further comprises the step of forming one or more optical devices at least partially within the monocrystalline silicon substrate in a region wherein each optical device is one of an optical detector and an optical source.

22. The method of claim 20, wherein the step of forming an enclosure comprises joining each edge of the semiconductor structure with an edge of another semiconductor structure to form a polyhedral structure.

23. The method of claim 22, wherein each semiconductor structure comprises one or more optical devices within the monocrystalline compound semiconductor layer, wherein each optical device is one of an optical detector and an optical source.

24. The method of claim 20, wherein the step of forming an enclosure comprises etching the enclosure from the semiconductor structure and exposing the one or more optical devices to the enclosure.

25. The method of claim 20 further comprising the step of providing a surface at least partially reflective to emissions from the optical source, wherein the step of forming an enclosure comprises spacing the surface substantially parallel to and apart from the semiconductor structure with the one or more optical devices facing the surface.

26. The method of claim 25, wherein the at least partially reflective surface is shaped to compensate for signal latency.

27. A method of communication between devices using an optical bus comprising:
generating a signal at a first device;
generating radiative emissions from an optical source in response to the signal, the optical source formed within a semiconductor structure comprising a monocrystalline silicon substrate, an amorphous oxide material overlying the monocrystalline substrate, a monocrystalline perovskite oxide material overlying the amorphous oxide material, and a monocrystalline compound semiconductor material overlying the monocrystalline perovskite oxide material;
detecting the radiative emissions at an optical detector formed within a second semiconductor structure comprising a monocrystalline silicon substrate, an amorphous oxide material overlying the monocrystalline substrate, a monocrystalline perovskite oxide material overlying the amorphous oxide material, and a monocrystalline compound semiconductor material overlying the monocrystalline perovskite oxide material;
re-generating the signal from the radiative emissions; and
transmitting the re-generated signal to a second device.
